(19) United States
(12) Patent Application Publication
(10) Pub. No.: US 2025/0220934 A1
(43) Pub. Date: Jul. 3, 2025

(54) Trench Capacitor and Method for Manufacturing the Same

(71) Applicant: Hangzhou Silicon-Magic Semiconductor Technology Co.,Ltd, Hangzhou (CN)

(72) Inventors: Yanqiang DU, Hangzhou (CN); Jiakun Wang, Hangzhou (CN)

(73) Assignee: Hangzhou Silicon-Magic Semiconductor Technology Co.,Ltd, Hangzhou (CN)

(21) Appl. No.: 18/986,761

(22) Filed: Dec. 19, 2024

(30) Foreign Application Priority Data
Dec. 28, 2023 (CN) 2023118452553

(51) Int. Cl. H10D 1/68; H10D 1/00; H10D 89/10

(52) U.S. Cl. CPC H10D 1/716; H10D 1/042; H10D 89/10

(57) ABSTRACT

The trench capacitor includes a semiconductor substrate, a trench array and at least one capacitor layer. The trench array has at least one trench segment disposed in the semiconductor substrate. Each one of the at least one trench segment comprises a plurality of inner trenches oriented lengthwise along a same direction, and a side trench bordering an outer edge of each one of the at least one trench segment. The inner trenches and the side trench in each one of the at least one trench segment are communicated with each other. The at least one capacitor layer conformally lines a surface of the semiconductor substrate which has the trench array. Each one of the at least one capacitor layer includes a dielectric layer and a conducting layer disposed on the dielectric layer.

### CROSS-REFERENCE TO RELATED APPLICATION

This application claims the benefit of Chinese Patent Application No. 202311845255.3, filed on Dec. 28, 2023, which is incorporated herein by reference in its entirety.

### TECHNICAL FIELD

The present disclosure relates to semiconductor devices and in particular to structure of trench capacitors and the method for manufacturing the same.

### BACKGROUND

Trench capacitors are widely used with integrated circuits (IC), integrated passive devices (IPD). A trench capacitor has a semiconductor substrate, trenches in the semiconductor substrate, and a capacitor layer that disposed on the semiconductor substrate and meanwhile lines the trenches.

The depth and the width of the trenches (aspect ratio) in the semiconductor substrate determines the surface area of the trench capacitor. The greater the circumference of the trenches, the larger the surface area of the trench capacitor. However, with the increase of the number of the capacitor layers, the space for the capacitor layers is decreasing. Consequently, the surface area of the trench capacitor is diminished, limiting the capacitance density of the trench capacitor.

### SUMMARY

In order to solve the technical problem in the prior art, the present disclosure provides a trench capacitor with increased capacitance density.

The embodiments of the present invention are directed to a trench capacitor. The trench capacitor includes a semiconductor substrate, a trench array and at least one capacitor layer. The trench array has at least one trench segment disposed in the semiconductor substrate. Each one of the at least one trench segment comprises a plurality of inner trenches oriented lengthwise along a same direction, and a side trench bordering an outer edge of each one of the at least one trench segment. The inner trenches and the side trench in each one of the at least one trench segment are communicated with each other. The at least one capacitor layer conformally lines a surface of the semiconductor substrate which has the trench array. Each one of the at least one capacitor layer includes a dielectric layer and a conducting layer disposed on the dielectric layer.

The embodiments of the present invention are directed to a method of forming a trench capacitor, including providing a semiconductor substrate; forming a trench array and a peripheral support structure bordering the trench array in the semiconductor substrate by etching the semiconductor substrate; and forming at least one capacitor layer on the semiconductor substrate. The capacitor layer conformally lines a respective surface of the semiconductor substrate which has the trench array and the peripheral support structure. Each one of the at least one capacitor layer includes a dielectric layer and a conducting layer. The trench array includes at least one trench segment. Each one of the at least one trench segment has a plurality of inner trenches oriented lengthwise along a same direction, and a side trench bordering an outer edge of the trench segment. The inner trenches and the side trench are communicated with each other in the respective one of the at least trench segment.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1 shows a cross-sectional view of a prior art trench capacitor 100.

FIG. 2 schematically shows a trench segment 102S of the trench capacitor 100.

FIG. 3 schematically shows a cross sectional view of a trench capacitor 200 in accordance with an embodiment of the present disclosure.

FIG. 4 schematically shows a trench segment 202S of the trench capacitor 200 in accordance with an embodiment of the present disclosure.

FIG. 5a schematically shows a trench array of the trench capacitor 200 in accordance with an embodiment of the present disclosure.

FIG. 5b schematically shows a cross sectional view along line AA of the trench array of the trench capacitor 200 as shown in FIG. 5a in accordance with an embodiment of the present disclosure.

FIG. 6 schematically shows a trench array of the trench capacitor 200 in accordance with an embodiment of the present disclosure.

FIG. 7 schematically shows a trench array of the trench capacitor 200 in accordance with an embodiment of the present disclosure.

FIGS. 8a to 8c schematically shows the cross sectional views of the trench capacitor during a manufacturing process in accordance with an embodiment of the present disclosure.

FIGS. 9a to 9d schematically shows the cross sectional views of the trench capacitor during a manufacturing process in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

Unless specifically noted below, portions of the semiconductor device may include materials well known to those skilled in the art. Semiconductor materials include, for example, III-V group semiconductors such as gallium arsenide (GaAs), gallium nitride (GaN), and the like, IV-IV group semiconductors such as silicon carbide (SiC), and the like, II-VI compound semiconductors such as cadmium sulfide (CdS), cadmium telluride (CdTe), and the like, and IV group semiconductors such as silicon (Si), germanium (Ge), and the like. The gate electrode may consist of or contain, as main constituent(s), aluminum (Al), copper (Cu), or alloys of aluminum or copper, for example AlSi, AlCu or AlSiCu. According to other embodiments, at least one of the gate electrodes may contain, as main constituents(s), nickel (Ni), tin (Sn), titanium (Ti), tungsten (W), tantalum (Ts), vanadium (V), silver (Ag), gold (Au), platinum (Pt), and/or palladium (Pd). For example, at least one of the gate load electrodes may include two or more sub-layers, wherein each sub-layer contains one or more of Ni, Sn, Ti, V, Ag, Au, Pt, W, and Pd as main constituent(s), e.g., a silicide, a nitride and/or an alloy. The gate dielectric may include SiO2. The gate dielectric may include or may consist of a semiconductor oxide, or a material having a dielectric constant greater than SiO2, including, for example, oxides, nitrides, nitrogen oxides, silicates, aluminates, titanates. Moreover, the gate dielectric may include not only materials known to those skilled in the art, but also materials developed in the future for use of insulation.

FIG. 1 shows a cross-sectional view of a prior art trench capacitor 100. As shown in FIG. 1, the trench capacitor 100 includes a semiconductor substrate 101, trenches 102 in the semiconductor substrate 101, and a capacitor layer 103 covering the semiconductor substrate 101 and lining in the trenches 102. The trenches 102 extend vertically from a surface into the interior of the semiconductor substrate 101. The capacitor layer 103 conformally lines the surface of the semiconductor substrate 101 and inner surfaces of the trenches 102.

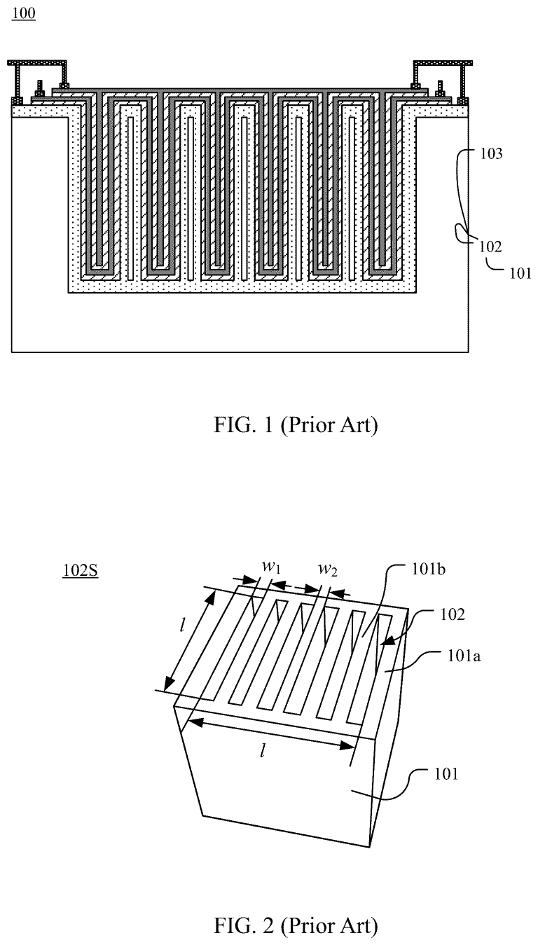

FIG. 2 schematically shows a trench segment 102S of the trench capacitor 100. As shown in FIG. 2, the semiconductor substrate 101 includes a peripheral support structure 101a and multiple extensions 101b. The multiple extensions 101b are positioned spaced from each other with a uniform distance between neighboring ones. The extension 101b are connected to the peripheral support structure 101a at the stripe ends from a top view. The peripheral support structure 101a together with the multiple extensions form trenches 102. One or a plurality of capacitor layers 103 conformally line the surface of the peripheral support structure 101a and the surface of the extensions 101b, i.e., the inner surface of the trenches 102.

In one embodiment, the inner contour of the peripheral support structure 101a forms a square with a side length of l. Assuming the trench segment 102S includes 5 extensions 101b and 6 trenches 102. Each of the extensions 101b has a width of w2, and a length of l. Each of the trenches 102 has a width of w1, a length of l, and a depth h. It could be obtained that l=6w1+5w2.

A contact area S11 of the capacitor layer 103 and the sidewalls of one of the trenches 102 could be expressed as: S11=2×(l+w1)×h.

Then the area S10 of the sidewalls of all of the trenches 102 in the trench segment 102S of the capacitor layer 103 could be expressed as:

$$S 10 = 6 \times 2 \times ( l + w 1 ) \times h = 12 \times ( 6 w 1 + 5 w 2 + w 1 ) \times h = ( 84 w 1 + 60 w 2 ) \times h .$$

As the number of the capacitor layers 103 increase, less room is left in the trenches of the trench segment 102S.

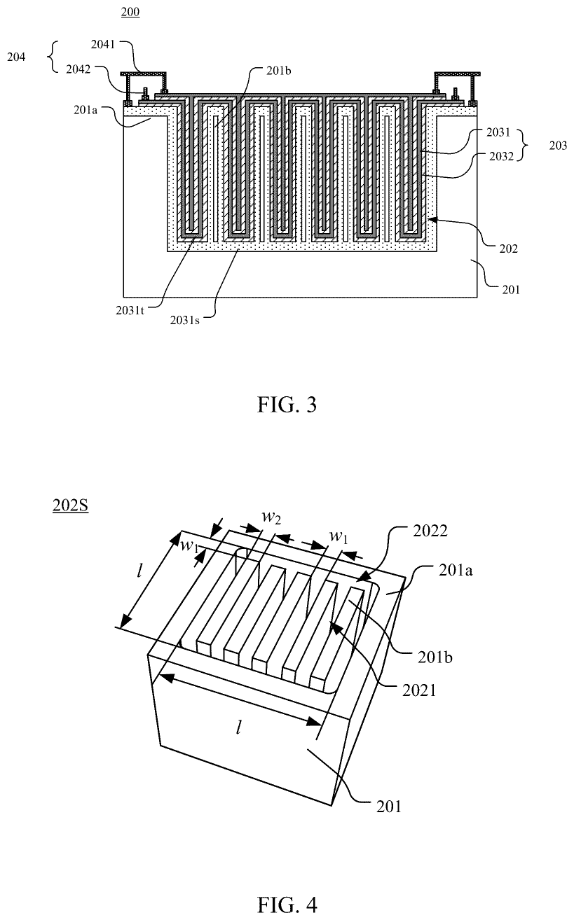

FIG. 3 schematically shows a cross sectional view of a trench capacitor 200 in accordance with an embodiment of the present disclosure. As shown in FIG. 3, the trench capacitor 200 includes a semiconductor substrate 201, trenches 202 and capacitor layers 203.

The semiconductor substrate 201 could be made of semiconductor materials, like Si, Ge, SOI (silicon on insulator), etc. The trenches 202 extend vertically from the surface to the interior of the semiconductor substrate 201. The capacitor layers 203 conformally lines the semiconductor substrate 201 and the trenches 202.

The trench capacitor 200 includes one or more than one capacitor layer 203. The capacitor layers 203 conformally line a surface of the semiconductor substrate 201 and the surface of extensions 202b, i.e., the inner surface of the trenches 202. When more than one capacitor layer 203 is configured, the capacitor layers are stacked.

Each of the capacitor layers 203 includes a conducting layer 2031 and a dielectric layer 2032. In the embodiments that more than one capacitor layer 203 is adopted, the conducting layers 2031 and the dielectric layers 2032 of the capacitor layers 203 are stacked alternately, such that the neighboring conducting layers 2031 are isolated from each other by the dielectric layer 2032. The conducting layer 2031 is made of conductive material, including but not limited to Al, W, TiN, doped poly-silicon, etc. The dielectric layer 2032 is made of insulating materials, including but not limited to SiO2, Si3N4, Al2O3, or any combination of SiO2, Si3N4, Al2O3, etc. The dielectric layer 2032 insulates the conducting layers 2031 from each other.

In one embodiment, the whole semiconductor substrate 201 or a top surface layer of semiconductor substrate 201 may be highly doped to have a high conductivity, and could serve as a substrate electrode layer 2031s. When the top layer of the semiconductor substrate 201 is highly doped and serves as the substrate electrode layer 2031s, it extends along the semiconductor substrate 201, covering the peripheral support structure 201a and the surface of the extensions 201b, i.e., the inner surface of the trenches 202. In one embodiment, the semiconductor substrate 201 could be the semiconductor materials with n-type dopants or the semiconductor materials with p-type dopants.

The trench capacitor 200 incudes contacting structures 204. The contact structure 204 includes a first contact structure 2041 and a second contact structure 2042. The first contact structure 2041 is electrically connected to some of the conducting layers 2031, and the second contact structure 2042 is electrically connected to the rest of the conducting layers 2031. In one embodiment, the conducting layer 2031 connected to the first contact structure 2041 and the conducting layer 2031 connected to the second contact structure 2042 are stacked from a plan view. In one embodiment, the first contact structure 2041 is configured as a cathode of the trench capacitor 200, the second contact structure 2042 is configured as an anode of the trench capacitor 200, and vice versa. The contact structures 204 could be made of any conductive materials, like Co, Al—Cu alloy, T, or any combination of the conductive materials.

FIG. 4 schematically shows a trench segment 202S of the trench capacitor 200 in accordance with an embodiment of the present disclosure. As shown in FIG. 4, the semiconductor substrate 201 includes the peripheral support structure 201a and the trench segment 202S surrounded by the peripheral support structure 201a. The trench segment 202S includes a plurality of inner trenches 2021 (also referred as the first trench) and a side trench 2022 (also referred as the second trench). The trenches 2021 and 2022 shape multiple extensions 201b on the semiconductor substrate 201. Each one of the extensions 201b has a square or rectangle shape from one of side views and has a stripe shape from a top view. The inner trenches 2023 are oriented lengthwise along a first direction, which is parallel to a side of the peripheral support structure 201a. The side trench 2022 borders an outer edge of the trench segment 202S, and is along an inner contour of the peripheral support structure 2042. Specifically, from a top view, the ends of the stripe-shaped extensions 201b are not connected to the peripheral support structure 201a. The first trenches 2021 and the second trench 2022 are communicated with each other. One or multiple capacitor layers 203 are disposed on the semiconductor substrate 201. The capacitor layers 203 conformally line the surfaces of the peripheral support structure 201a and the extensions 201b, i.e., line the inner surfaces of the first trenches 2022 and the second trenches 2022.

The width of the trench between the neighboring extensions 201b is equal to the distance between the ends of the extensions 201 from and the peripheral support structure 201a from the top view. In other words, the width of the first trenches 2021 is equal to the width of the second trench 2022. When the first trenches 2021 and the second trench 2022 have different widths, some of the trenches may be fully filled by the capacitor layers 203 while some of the trenches are not. Consequently, the structural stress of the trench capacitor is uneven. To avoid such kind of the uneven structural stress, the widths of first trenches 2021 and the second trench 2022 of the trench capacitor 200 are set to be equal.

In the embodiment of FIG. 4, the surface of the semiconductor substrate 201 which has the trench segment covered by the capacitor layers 203. In one embodiment, the inner contour of the peripheral support structure 201a forms a square having a side length of l. The trench segment 202S accommodates 5 extensions 201b, and each one of the extensions 201b has a width of w2. Both of the first trenches 2021 and the second trench 2022 have a width of w1, and a depth of h. Then, the length l could be expressed as: l=6w1+5w2, and a length l1 of each extension 201b from a top view could be expressed as: l1=l−2w1.

In the embodiment of FIG. 4, the area S21 of the sidewalls of each extension 201b contacting the capacitor layer 203 could be expressed as: S21=2×(l1+w2)×h. Simplification by use of l1=l−2w1 and l=6w1+5w2 yields: S21=2×(l1+w2)×h=2×(l−2w1+w2)×h=(8w1+l2w2)×h.

The area S22 of the inner sidewalls of the peripheral support structure 201a contacting the capacitor layer 203 could be expressed as S22=4×l×h. Simplification by use of l=6w1+5w2 yields: S22=4×l×h=4×(6w1+5w2)×h=(24w1+20w2)×h.

The area S20 of a surface of the trench segment 202S as shown in FIG. 4 could be written as S20=5×S21+S22. Simplification by use of S21=(8w1+12w2)×h and S22=(24w1+20w2)×h yields S20=5×(8w1+12w2)×h+(24w1+20w2)×h=(64w1+80w2)×h.

To get a larger area for contacting the capacitor layer than prior art, S20 should be larger than S10, i.e., S20>S10. Substitution of S20=(64w1+80w2)×h and S10=(84w1+60w2)×h into S20>S10 yields w2>w1.

That is to say, by adopting the structure of the embodiment in FIG. 4, and making sure that the width w2 of each extension 201b be larger than the width w1 of each one of the first trenches 2021 and the second trench 2022, a larger than prior art contacting area of semiconductor substrate to the capacitor layer in a trench capacitor could be obtained, leading to a larger capacitance in a given size of the trench capacitor. In FIG. 4, a first capacitor layer 203 has the area of S20 contacting the extensions 201b and the peripheral support structure 201a. In the embodiments which has a second capacitor layer stacking on the first capacitor layer, the area of the second capacitor layer contacting the first capacitor layer is even larger than the area of S20, since the first capacitor layer extends the length and width of the extensions 201b, i.e., the second capacitor layer covering the first capacitor layer has a contact area of S23=2×(l1+2×w3+w2+2×w3)×h, wherein w3 is the thickness of the layer of the first capacitor layer. By this analogy, a third capacitor layer and the second capacitor layer has a larger contact area than the contact area of the second capacitor layer and the first capacitor layer. However, in the prior art in FIG. 2, the second capacitor layer covering the first capacitor layer has a contact area of S13=2×(l1+w2+2×w3)×h, which is smaller in the increase of the area. Larger contact area results in a greater capacitance of the capacitor layer. Thus, when more capacitor layers are stacked, the capacitance of the trench capacitor of the embodiments of the present disclosure is increased more than that of the trench capacitor in the prior art.

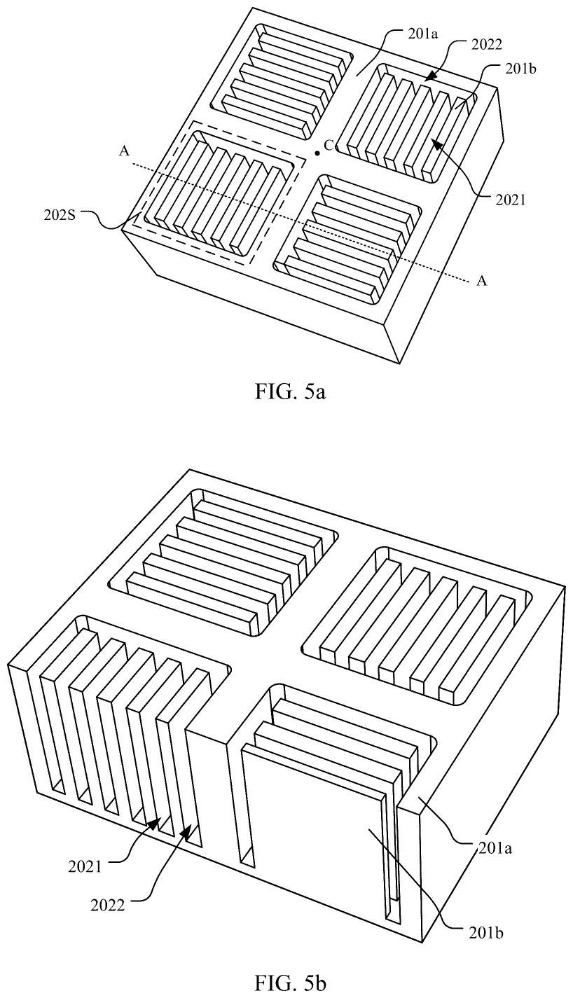

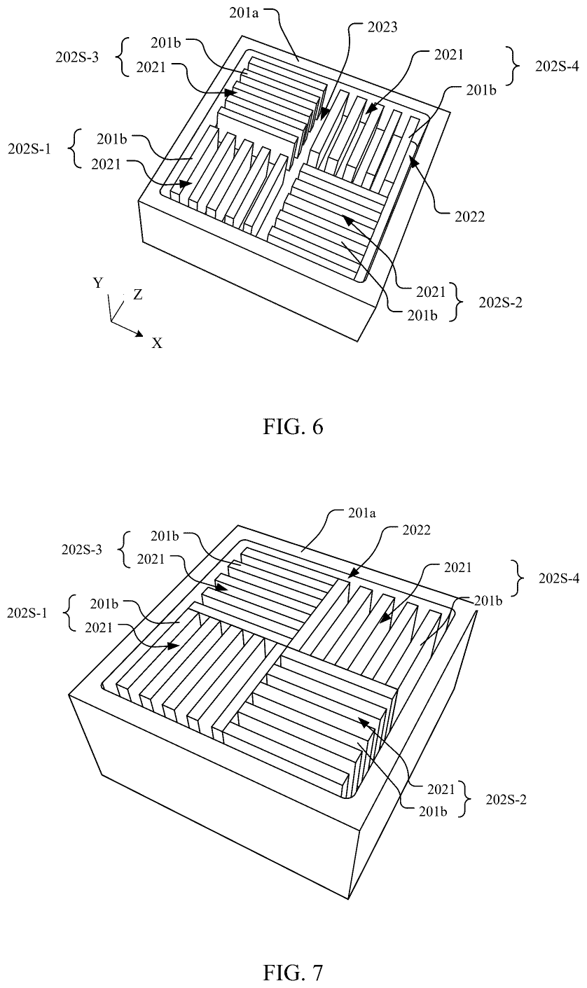

FIG. 5a schematically shows a trench array of the trench capacitor 200 in accordance with an embodiment of the present disclosure. FIG. 5b schematically shows a cross sectional view along line AA of the trench array of the trench capacitor 200 as shown in FIG. 5a in accordance with an embodiment of the present disclosure. As shown in FIGS. 5a and 5b, the semiconductor substrate 201 includes the peripheral support structure 201a and multiple trench segments 202S. The peripheral support structure 201a surrounds each trench segment 202S, i.e., the trench segments 202S are isolated from each other by the peripheral support structure 201a.

In one embodiment, the trench capacitor 200 in the embodiment of FIGS. 5a and 5b includes N trench segments 202S forming a trench array, wherein N is an integer larger than 1. The trench segments 202S of the trench array are arranged in a rotationally symmetric pattern. By rotationally symmetric pattern, it means that one trench segment 202S could be fully overlapped by a neighboring trench segment 202S if the neighboring trench segment 202S rotates R degrees around a center point C as shown in the center of the trench array in FIG. 5a, wherein R equals to 360°/N, and N is an integer.

In one embodiment, N=4. Then it could be obtained that R=90°. In that case, the lengthwise of the inner trenches 2021 in one trench segment 202S are oriented in a direction which is perpendicular to a direction that the inner trenches 2021 in the neighboring trench segment 202S are oriented in, which means that one trench segment 202S rotates approximately 90 degrees with respect to the neighboring trench segment 202S.

The trench capacitor 200 having the trench array in the embodiment in FIG. 5a reduces the stress induced by etching the trenches in a uniform layout in prior art.

FIG. 6 schematically shows a trench array of the trench capacitor 200 in accordance with an embodiment of the present disclosure. As shown in FIG. 6, the semiconductor substrate 201 includes the peripheral support structure 201a and multiple trench segments 202S. Different from the embodiment in FIG. 5a, the peripheral support structure 201a forms a frame surrounding the multiple trench segments 202S of the trench array, wherein the peripheral support structure 201a is devoid between the trench segments 202S. That is to say, instead of each trench segment 202S surrounded by the peripheral support structure 201a, four trench segments 202S, as a group, are surrounded by the peripheral support structure 201a. Each trench segment 202S is positioned spaced from the neighboring trench segment 202S to form third trenches 2023 between the trench segments 202S. From another perspective, the sections of the second trenches 2022 between the trench segments 202S forms a common trench, i.e., the third trench 2023. The first trenches 2021, the second trenches 2022 and the third trenches 2023 are communicated to each other.

In the embodiment of FIG. 6, the semiconductor substrate 201 includes the peripheral support structure 201a, and a trench array including four trench segments 202S, specifically, a first trench segment 202S-1, a second trench segment 202S-2, a third trench segment 202S-3 and a fourth trench segment 202S-4. The lengthwise of the first trenches 2021 in the first trench segment 202S-1 are oriented in a direction that is perpendicular to a direction that the lengthwise of the first trenches 2021 in a neighboring trench segment 202S are oriented in.

In the example of FIG. 6, the lengthwise of the first trenches 2021 in the first trench segment 202S-1 are oriented in a first direction (along the Z-axis in FIG. 6), and the lengthwise of the first trenches 2021 in the second trench segment 202S-2 and the third trench segment 202S-3 are oriented in a second direction (along the X-axis in FIG. 6). Along the inner contour of the peripheral support structure 201a, there forms a second trench 2022. Between every two trench segments, there forms a third trench 2023.

FIG. 7 schematically shows a trench array of the trench capacitor 200 in accordance with an embodiment of the present disclosure. As shown in FIG. 7, the semiconductor substrate 201 includes the peripheral support structure 201a and multiple trench segments 202S. Different from the embodiment in FIG. 6, the third trenches 2023 between the trench segments 202S are omitted to further increase the capacitance density of the trench capacitor.

In the embodiment of FIG. 7, the semiconductor substrate 201 includes the peripheral support structure 201a, and a trench array including four trench segments 202S, specifically, a first trench segment 202S-1, a second trench segment 202S-2, a third trench segment 202S-3 and a fourth trench segment 202S-4. The lengthwise of the first trenches 2021 in the first trench segment 202S-1 is oriented in a first direction (along the Z-axis in FIG. 7). The lengthwise of the first trenches 2021 in the neighboring second trench segment 202S-2 and third trench segment 202S-3 are oriented in a second direction (along the X-axis in FIG. 7) which is perpendicular to the first direction.

In the example of FIG. 7, the extensions 201b in the first trench segment 202S-1 are positioned spaced from the peripheral support structure 201a, so are the extensions 201b in the second trench segment 202S-2, the third trench segment 202S-3 and the fourth trench segment 202S-4, forming the second trench 2022 along the inner contour of the peripheral support structure 201a. Between every two trench segments, there is devoid of the third trench 2023, which is different from the embodiment in FIG. 6. That is to say, the extensions in the first trench segment 202S-1 physically contact the a first extension in the third trench segment 202S-3, the extensions in the third trench segment 202S-3 physically contact the a first extension in the fourth trench segment 202S-4, the extensions in the fourth trench segment 202S-4 physically contact the a first extension in the second trench segment 202S-2, and the extensions in the second trench segment 202S-2 physically contact the a first extension in the first trench segment 202S-1, as shown in FIG. 7.

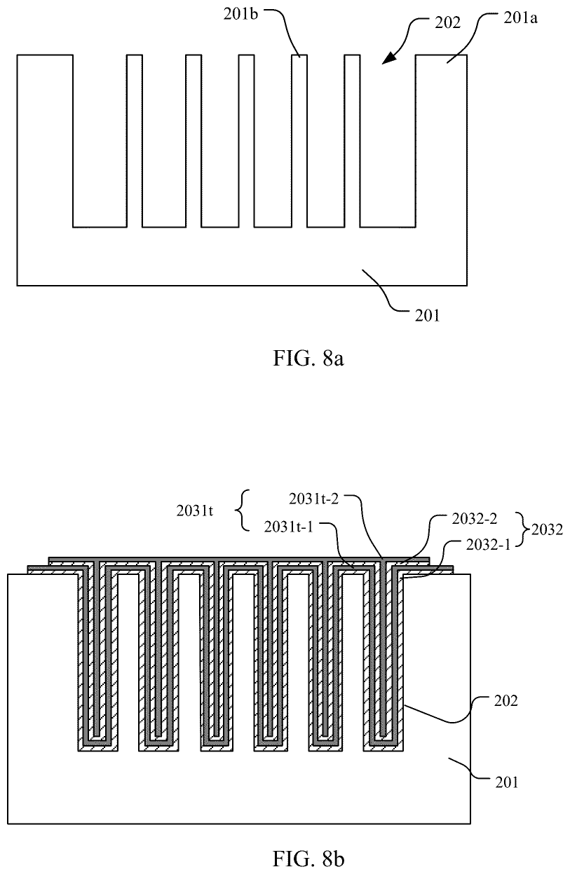

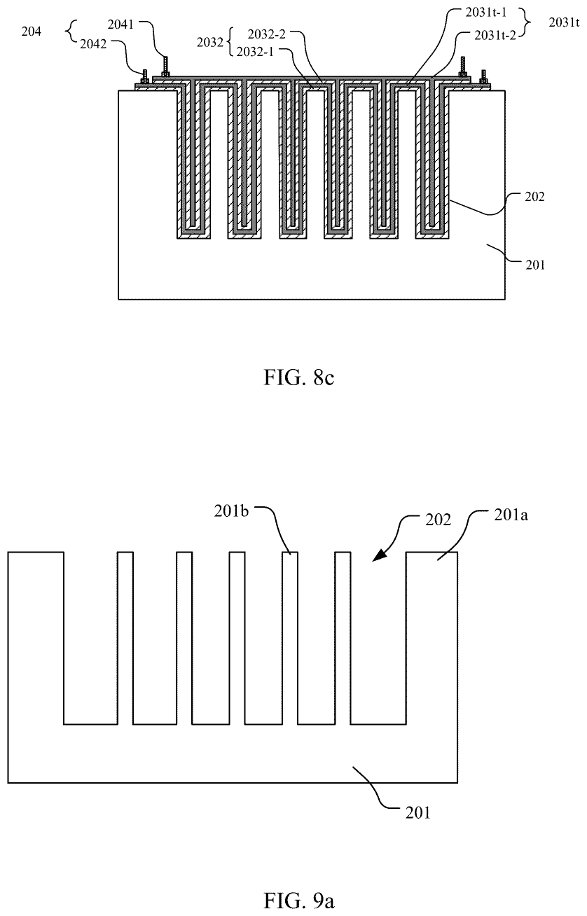

FIGS. 8a to 8c schematically shows the cross sectional views of the trench capacitor during a manufacturing process in accordance with an embodiment of the present disclosure.

As shown in FIG. 8a, the semiconductor substrate 201 is etched to have trenches after a photolithographic process. The semiconductor substrate 201 is etched to have the peripheral support structure 201a and extensions 201b. The extensions 201b are positioned spaced from each other so that to have first trenches 2021 in between. Meanwhile, the extensions 201b are isolated from the peripheral support structure 201a, so that second trench 2022 are formed along the inner contour of the peripheral support structure 201a. Specifically, from the top view, the ends of the stripe-shaped extensions 201b are not connected to the peripheral support structure 201a, forming sections of the second trench 2022. Also, the extensions 201b which are close to the peripheral support structure 201a are distanced from the peripheral support structure 201a to form sections of the second trench 2022. The first trenches 2021 are communicated to the second trench 2022. Furthermore, the first trenches 2021 and the second trench 2022 have a same width.

The semiconductor substrate 201 could be made of semiconductor materials like silicon and germanium. In some embodiments, the semiconductor substrate 201 is a semiconductor on insulator. The semiconductor substrate 201 could have any suitable doping concentration, and could have p-type dopants or n-type dopants as required.

As shown in FIG. 8b, capacitor layers 203 are disposed on a surface of the semiconductor substrate 201.

On the surface of the semiconductor substrate 201, the dielectric layers 2032 and the conducting layers 2031t are alternately stacked, so that the neighboring conducting layers 2031t are insulated from each other. The conducting layers 2031t are made of conductive material, including but not limited to Al, W, TiN, doped poly-silicon, etc. The dielectric layer 2032 is made of insulating material, including but not limited to SiO2, Si3N4, Al2O3, or any combination of SiO2, Si3N4, Al2O3, etc. The dielectric layer 2032 insulates the conducting layers 2031t from each other.

The dielectric layers 2032 are formed by processes like thermal oxidation, PVD, CVD or LPCVD. Each dielectric layer 2032 may have a substantially uniform thickness in the order of tens of nanometers. When formed by processes like ALD (Atomic Layer Deposition), PVD (Physical Vapor Deposition), CVD (chemical vapor deposition), and are made of metals like Al, W and TIN, the conducting layers 2031t have a substantially uniform thickness in the order of tens of nanometers. When made of polysilicon, the conducting layer 2031t may have a thickness of less than 1 micrometer.

In the embodiment of FIG. 8b, the first dielectric layer 2032-1, the first conducting layer 2031t-1, the second dielectric layer 2032-2 and the second conducting layer 2031t-2 are formed subsequently. The first dielectric layer 2032-1 and the first conducting layer 2031t-1 form a capacitor layer, and the second dielectric layer 2032-2 and the second conducting layer 2031t-2 form another capacitor layer.

In FIG. 8c, the contact structures 204 are formed.

The contact structures 204 includes the first contact structure 2041 and the second contact structure 2042. The first contact structure 2041 is formed on the second conducting layer 2031t-2, and the second contact structure 2042 is formed on the first conducting layer 2031t-1. In one embodiment, the conducting layer connected to the first contact structure 2041 are insulated from the conducting layer connected to the second contact structure 2042. The first contact structure 2041 may be configured as a cathode of the trench capacitor 200, and the second contact structure 2042 may be configured as an anode of the trench capacitor 200, vice versa. The conduct structures 204 include wires made of metals, like copper, aluminum copper, aluminum, tungsten, any combination of these metals, or other conductive materials.

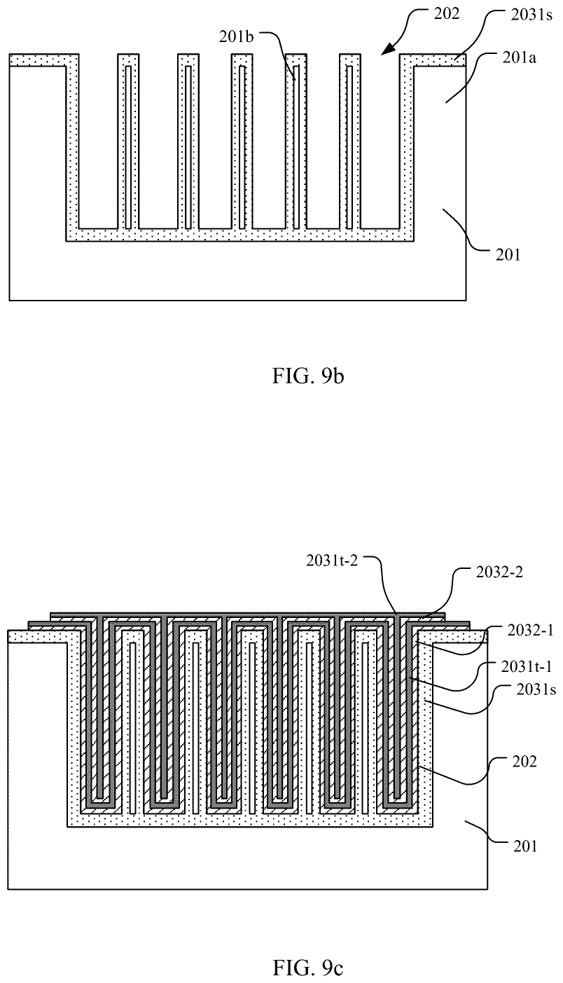

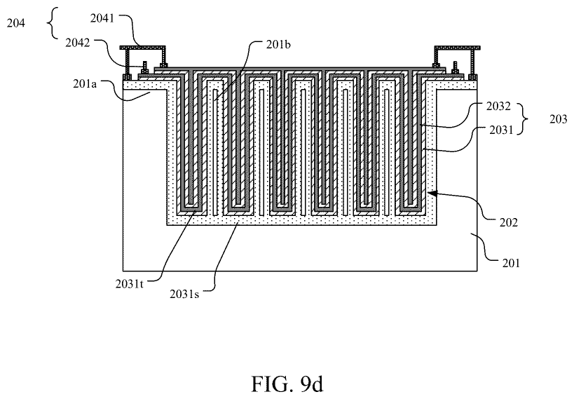

FIGS. 9a to 9d schematically shows the cross sectional views of the trench capacitor during a manufacturing process in accordance with an embodiment of the present disclosure.

In FIG. 9a, the semiconductor substrate 201 is etched to have trenches, like the embodiment in FIG. 8a, and is not illustrated for brevity.

In FIG. 9b, the substrate electrode layer 2031s is formed.

When the semiconductor substrate 201 has a low doping concentration, the top surface of the semiconductor substrate 201 could be doped with n-type dopants or p-type dopants to form the substrate electrode layer 2031s. It should be noted that this step could be omitted when the semiconductor substrate 201 has a high doping concentration.

In FIG. 9c, capacitor layers 203 are disposed on the semiconductor substrate 201. On the surface of the semiconductor substrate 201, the dielectric layers 2032 and the conducting layers 2031t are alternately stacked, so that the neighboring conducting layers 2031t are insulated from each other. In the embodiment of FIG. 9c, the first dielectric layer 2032-1, the first conducting layer 2031t-1, the second dielectric layer 2032-2 and the second conducting layer 2031t-2 are formed subsequently. The first dielectric layer 2032-1 and the first conducting layer 2031t-1 form a capacitor layer, and the second dielectric layer 2032-2 and the second conducting layer 2031t-2 form another capacitor layer.

In FIG. 9d, the contact structures 204 are formed.

The contact structures 204 includes the first contact structure 2041 and the second contact structure 2042. The first contact structure 2041 is formed on the second conducting layer 2031t-2, and the second contact structure 2042 is formed on the first conducting layer 2031t-1. In one embodiment, the conducting layer connected to the first contact structure 2041 are insulated from the conducting layer connected to the second contact structure 2042. The first contact structure 2041 may be configured as a cathode of the trench capacitor 200, and the second contact structure 2042 may be configured as an anode of the trench capacitor 200, vice versa. The conduct structures 204 include wires made of metals, like copper, aluminum copper, aluminum, tungsten, any combination of these metals, or other conductive materials.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

1. A trench capacitor, comprising:
a semiconductor substrate;
a trench array having at least one trench segment disposed in the semiconductor substrate, wherein each one of the at least one trench segment comprises a plurality of inner trenches oriented lengthwise along a same direction, and a side trench bordering an outer edge of each one of the at least one trench segment, and wherein the inner trenches and the side trench in each one of the at least one trench segment are communicated with each other; and
at least one capacitor layer conformally lining a surface of the semiconductor substrate which has the trench array, and wherein each one of the at least one capacitor layer comprises a dielectric layer and a conducting layer disposed on the dielectric layer.

2. The trench capacitor of claim 1, wherein the semiconductor substrate comprises a peripheral support structure bordering each one of the at least one trench segment.

3. The trench capacitor of claim 1, wherein the trench array comprises more than one trench segment, and wherein the semiconductor substrate comprises a peripheral support structure bordering the trench array, and wherein the peripheral support structure is devoid between the trench segments in the trench array.

4. The trench capacitor of claim 1, wherein the trench array comprises more than one trench segment, and wherein sections of the side trench between the trench segments in the trench array are devoid.

5. The trench capacitor of claim 1, wherein the semiconductor substrate comprises a substrate electrode layer in a top surface layer of the semiconductor substrate.

6. The trench capacitor of claim 5, wherein the substrate electrode layer and the conducting layer of a respective one of the at least one capacitor layer are electrically connected by contacting structures.

7. The trench capacitor of claim 1, wherein a width of each one of the inner trenches is equal to a width of the side trench in each one of the at least one trench segment.

8. The trench capacitor of claim 1, wherein a distance between the neighboring inner trenches is larger than a width of each one of the inner trenches in each one of the at least one trench segment.

9. The trench capacitor of claim 1, wherein the trench array comprises more than one trench segments, and the trench segments in the trench array in a respective row are aligned with one another, and the trench segments in the trench array in a respective column are aligned with one another.

10. The trench capacitor of claim 1, wherein the trench array comprises more than one trench segments, and a trench segment is rotationally symmetric to respective neighboring trench segments in the trench array.

11. The trench capacitor of claim 1, wherein the trench array comprises more than one trench segments, and a trench segment overlaps a respective neighboring trench segment by being rotated substantially 90 degrees around a center point of the trench array.

12. The trench capacitor of claim 1, wherein the conducting layer of one of the at least one capacitor layer comprises polysilicon.

13. The trench capacitor of claim 1, wherein the dielectric layer of one of the at least one capacitor layer comprises SiO2, Si3N4 and Al2O3.

14. A method of forming a trench capacitor, comprising:
providing a semiconductor substrate;
forming a trench array and a peripheral support structure bordering the trench array in the semiconductor substrate by etching the semiconductor substrate; and
forming at least one capacitor layer on the semiconductor substrate, wherein the capacitor layer conformally lines a respective surface of the semiconductor substrate which has the trench array and the peripheral support structure, and wherein each one of the at least one capacitor layer comprises a dielectric layer and a conducting layer;
wherein the trench array comprises at least one trench segment, and wherein each one of the at least one trench segment has a plurality of inner trenches oriented lengthwise along a same direction, and a side trench bordering an outer edge of the trench segment, and wherein the inner trenches and the side trench are communicated with each other in the respective one of the at least trench segment.

15. The method of claim 14, wherein a width of each one of the inner trenches is equal to a width of the side trench in each one of the at least one trench segment.

16. The method of claim 14, wherein a distance between the neighboring inner trenches is larger than a width of each one of the inner trenches in each one of the at least one trench segment.

17. The method of claim 14, wherein the peripheral support structure borders each one of the at least one trench segment of the trench array.

18. The method of claim 14, wherein the at least one capacitor layer comprises a first capacitor layer and a second capacitor layer, and wherein the method further comprising:
forming a first contact structure connecting the conducting layer of the first capacitor layer, wherein the contact structure is configured as one of the anode and cathode of the trench capacitor; and
forming a second contact structure connecting the conducting layer of the second capacitor layer, wherein the second contact structure are configured as the other one of the anode and cathode of the trench capacitor.

19. The method of claim 14, wherein before forming at least one capacitor layer on the semiconductor substrate, further comprising:
forming a substrate electrode layer in a top surface layer of the semiconductor substrate by implanting dopants into the semiconductor substrate.

20. The method of claim 19, wherein the at least one capacitor layer comprises a first capacitor layer and a second capacitor layer, and wherein the method further comprising:
forming a first contact structure connecting the conducting layer of the first capacitor layer, wherein the first contact structure is configured as one of the anode and cathode of the trench capacitor; and
forming a second contact structure connecting the conducting layer of the second capacitor layer and the substrate electrode layer, wherein the second contact structure is configured as the other one of the anode and cathode of the trench capacitor.
